(19) United States
(12) Patent Application Publication
(10) Pub. No.: US 2006/0276980 A1
(43) Pub. Date: Dec. 7, 2006

(54) Method and apparatus for detecting charged state of secondary battery based on neural network calculation

(75) Inventors: Satoru Mizuno, Nishio-shi (JP); Atsushi Hashikawa, Okazaki-shi (JP); Shoji Sakai, Toyota-shi (JP); Takaharu Kozawa, Kounan-shi (JP); Naoki Mizuno, Nagoya (JP); Yoshifumi Morita, Gifu-shi (JP)

Correspondence Address: OLIFF & BERRIDGE, PLC, P.O. BOX 19928, ALEXANDRIA, VA, 22320, US

(73) Assignees: DENSO CORPORATION, Kariya-city (JP); NIPPON SOKEN, INC., Nishio-city (JP); NATIONAL UNIVERSITY CORPORATION NAGOYA INSTITUTE OF TECHNOLOGY, Showa-ku (JP)

(21) Appl. No.: 11/407,112

(22) Filed: Apr. 20, 2006

(30) Foreign Application Priority Data
Apr. 20, 2005 (JP) 2005-122009
Apr. 20, 2005 (JP) 2005-122030

(51) Int. Cl. H02J 7/00; G01R 31/36

(52) U.S. Cl. 702/63; 320/128

(57) ABSTRACT

An apparatus and method of neural network type are provided to detect an internal state of a secondary battery implemented in a battery system. Electric signals indicating an operating state of the battery is detected and, using the electric signals, information indicating the internal state of the battery is calculated on the basis of neural network calculation, in which the information reflects a reduction in an effect of polarization of the secondary battery. Using the electric signals, input parameters required for calculating the internal state of the battery is calculated. The input parameters may include, as one input parameter, a polarization-related quantity to correct the effect of the polarization in an output parameter (such as SOC and/or SOH) from the neural network. Further, the input parameters may include, as one input parameter, a functional value already subjected to the correction for correcting the effect of the polarization.

### CROSS REFERENCES TO RELATED APPLICATIONS

The present application relates to and incorporates by reference Japanese Patent application Nos. 2005-122009 filed on Apr. 20, 2005 and 2005-122030 filed on April 20, 2005.

### BACKGROUND OF THE INVENTION

1. Field of the Invention

The present invention relates to a battery system with a neural network type of apparatus for detecting a charged state of a secondary (rechargeable) battery, and in particular, to an improvement in detection of internal stages (such as charged states) of the battery which is for example mounted on vehicles.

2. Description of the Related Art

An on-vehicle battery system is mostly composed of a secondary battery such as a lead battery. In such a secondary battery, a degree of degradation gives fluctuations to correlations between electric quantities of a battery, such as voltage and current, and charged state quantities of the battery, such as an SOC (state of charge) and an SOH (state of health). The SOC indicates a charged rate [%] of a battery and the SOH indicates a residual capacity [Ah] of a battery. Thus, as the degradation advances in the battery, the precision in detecting the SOC and/or SOH will also be degraded, whereby the SOC and/or SOH will fluctuate battery by battery. These problems make it difficult to detect, with precision, the SOC and/or SOH of each of secondary batteries which are mass-produced. Therefore, to avoid such fluctuations on the safe side, the fluctuations should be taken into account in a usable charge and discharge range of each second battery, with the result that the range is obliged to be narrower.

Some known references, which are for instance Japanese Patent Laid-open Publications Nos. 9-243716 and 2003-249271, propose a technique to improve the above situation. That is, those references propose how to detect the SOC and/or SOH of a secondary battery with the use of neural network (, which is called “neural network type of detection of battery state”).

For example, the publication No. 9-243716 provides a technique of detecting the residual capacity Te of a battery, in which input parameters including at least an open-circuit voltage OCV, a voltage VO detected immediately after starting a discharge, and an internal resistance R are used for allowing a leaned neutral network to calculate the residual capacity Te. The publication No. 2003-249271 also provides a technique of detecting the residual capacity of a battery, in which data of voltage, current and internal resistance of a battery and a temperature are inputted to a first learned neural network to calculate information showing degradations of the battery, and this information and the data of voltage, current and internal resistance of the battery are then inputted to a second learned neural network to calculate the residual capacity of the battery.

However, in cases where the SOC and/or SOH of a secondary battery are calculated based on the techniques provided by the foregoing publications, the residual capacity of the secondary battery results in detection with poor precision, even though both the circuitry size and the calculation load for such techniques are required to be larger compared to a residual-capacity detection technique with no neural network calculation. Therefore, first of all, for practical use, the detection has been short of the precision. It is therefore required to raise the precision much further. Secondly, it is required that the detection on the neural network calculation be raised more with both the circuitry size and the calculation amount kept lowered (at least, avoided from being increasing).

### SUMMARY OF THE INVENTION

The present invention has been completed with the above view in mind and has an object to provide a method and apparatus for detecting, with precision, information indicative of the residual capacity of a secondary battery on the basis of neural network calculation, with both the size of circuitry and with the amount of calculation avoided from increasing excessively.

To achieve the above object, as a fundamental aspect of the present invention, there is provided a neural network type of apparatus for detecting an internal state of a secondary battery implemented in a battery system, the apparatus comprising: detecting means for detecting electric signals indicating an operating state of the battery; and calculating means for calculating, using the electric signals, information indicating the internal state of the battery on the basis of neural network calculation, the information reflecting a reduction in an effect of polarization of the secondary battery.

Practically, the internal state of the battery is a charged state of the battery and includes an SOH (state of health) and an SOC (state of charge).

It is preferred that the calculating means includes producing means for producing, using the electric signals, an input parameter required for calculating the internal state of the battery, the input parameter including i) a polarization-related quantity relating to a charge and discharge current flowing during a latest predetermined period of time which affecting an amount of polarization of the secondary battery and ii) data indicating a voltage of a the secondary battery and a current from and to the secondary battery; and estimating means for estimating an output parameter serving as the information indicating the internal state of the battery by applying the input parameter to the neural network calculation.

The polarization-related quantity is for example a current-integrated value obtained by integrating current acquired during the latest predetermined period for calculation. An amount of polarization caused in a secondary battery has a high correlation with an integrated value of charge/discharge current integrated during the latest short period of time predetermined for calculation (measurement). Such period is for example 5 to 10 minutes. Thus, by using the simple calculation (in this case, integration), the polarization-related quantity which expresses the actual polarization quantity very well can be calculated.

When the input parameters include, part thereof, the polarization-related quantity, the amount of calculation necessary for the neural network calculation does not increase so much. With the amount of calculation kept at a moderate one or with a rise in the amount of calculation kept low, taking the polarization-related quantity into considering as part of the input parameters allows the charge state of the battery to be calculated with precision, compared to calculation with no such polarization-related quantity considered.

This is based on the fact that the voltage of the secondly battery is affected by the polarization caused in the battery. Thus adding the polarization-related quantity, as a parameter, to the input parameters for the neural network calculation makes it possible to cancel a polarization voltage component included in the voltage. The polarization voltage component is reactive in obtaining the output parameter. The cancellation leads to an improvement of the precision in estimating the internal state of the battery.

Accordingly, by adding only one parameter (the polarization-related quantity), the internal state (charged state) of the battery can be detected with high precision, while still keeping the calculation amount lower.

It is also preferred that the calculating means includes producing means for producing, using the electric signals, an input parameter required for calculating the internal state of the battery, the input parameter including a functional value correlating to the internal state of the secondary battery, the functional value reflecting the reduction in an effect of polarization of the secondary battery; and estimating means for estimating an output parameter serving as the information indicating the internal state of the battery by applying the input parameter to the neural network calculation.

This preferred embodiment of the present invention is realized on the fact that the functional value (e.g., open-circuit voltage and internal resistance) extracted from the data of the battery internal state (e.g., voltage/current paired history data) is largely affected by the polarization of the battery. In particular, this preferred embodiment is realized by considering the fact that the foregoing open-circuit voltage and internal resistance fluctuate depending on a degree of the polarization caused in the battery.

Accordingly, the functional value, which is composed of for example an open-circuit voltage and an internal resistance and correlates to a charged quantity (or degraded quantity) of the battery, is avoided from being influenced by the polarization. By using, as part of the input parameters, the functional value (e.g., the open-circuit voltage and internal resistance) which has already been almost released from the influence of the polarization, the neural network calculation can therefore be made with higher precision. Thus the similar advantages to the above can be provided, in addition to being less delay of the calculation, because the number of input parameters is not changed at all (that is, part of the input parameters is replaced by new one(s) from which the influence of the polarization has already been removed well).

As another aspect of the present invention, there is provided a method of detecting an internal state of a secondary battery implemented in a battery system, comprising steps of: detecting electric signals indicating an operating state of the battery; and calculating, using the electric signals, information indicating the internal state of the battery on the basis of neural network calculation, the information reflecting a reduction in an effect of polarization of the secondary battery.

### BRIEF DESCRIPTION OF THE DRAWINGS

In the accompanying drawings:

FIG. 1 is a block diagram showing the circuitry of an on-vehicle battery system adopted by a first embodiment according to the present invention;

FIG. 2 is a block diagram showing the configuration of a battery state detector employed by the first embodiment;

FIG. 3 is a timing chart explaining acquisition of signals of voltage and current and calculation of data of both an open-circuit voltage and an internal resistance of a battery in the on-vehicle battery system;

FIG. 4 is a two-dimensional map showing how to estimate an approximate expression used to calculate both an open-circuit voltage and an internal resistance of the battery installed in the battery state detector;

FIG. 5 is a flowchart explaining how to calculate a quantity indicating a charged state (i.e., internal state) of the battery;

FIG. 6 is a functional block diagram explaining the functional configuration of a neural network calculator employed by the battery state detector;

FIG. 7 is a flowchart showing the processing executed by the neural network calculator;

FIG. 8 is a table exemplifying various used batteries used for experiments according to the first embodiment;

FIGS. 9-11 are graphs each showing test results for an SOC with using the latest current-integrated quantity Qx, the tests being conducted according to the input parameters according to the first embodiment;

FIGS. 12-14 are graphs each showing test results for an SOC without using the latest current-integrated quantity Qx, the graphs providing materials for comparison with those in FIGS. 9-11 in the first embodiment;

FIG. 15 shows the waveform of the latest current-integrated quantity Qx used for the comparison;

FIG. 16 shows changes in the open-circuit voltage that correlate highly with the current-integrated quantity Qx;

FIG. 17 is a block diagram showing the circuitry of an on-vehicle battery system adopted by a second embodiment according to the present invention;

FIG. 18 is a functional block diagram explaining the functional configuration of a neural network calculator employed by the battery state detector in the second embodiment;

FIGS. 19-21 are graphs each showing test results for an SOC with using the latest current-integrated quantity Qx, the tests being conducted according to the input parameters according to the second embodiment;

FIGS. 22-24 are graphs each showing test results for an SOC without using the latest current-integrated quantity Qx, the graphs providing materials for comparison with those in FIGS. 19-21 in the second embodiment;

FIG. 25 is a block diagram showing the circuitry of an on-vehicle battery system adopted by a third embodiment according to the present invention;

FIG. 26 is a flowchart explaining how to calculate a quantity indicating a charged state (i.e., internal state) of the battery in the third embodiment;

FIG. 27 is a functional block diagram explaining the functional configuration of a neural network calculator employed by the battery state detector in the third embodiment;

FIGS. 28-30 are graphs each showing test results for an SOC, the tests being conducted with the use of a correction technique applied to part of the input parameters according to the third embodiment;

FIGS. 31-33 are graphs each showing test results for an SOC, the tests, conducted without the use of the correction technique, providing materials for comparison with those in FIGS. 28-30 in the third embodiment;

FIG. 34 is a graph for obtaining a correspondence between the SOC and the open-circuit voltage in the case of the test shown in FIG. 28;

FIG. 35 is a graph for obtaining a correspondence between the SOC and the open-circuit voltage in the case of the test shown in FIG. 31;

FIG. 36 is a graph for obtaining a correspondence between the SOC and the internal resistance in the case of the test shown in FIG. 28;

FIG. 37 is a graph for obtaining a correspondence between the SOC and the internal resistance in the case of the test shown in FIG. 31;

FIG. 38 is a graph exemplifying temporal changes in the voltage V, current I and polarization index Pn; and

FIG. 39 illustrates charged states of both a brand new battery and a used (degraded) battery and the definitions of an SOH, SOC and full charge capacity.

### DETAILED DESCRIPTION OF PREFERRED EMBODIMENTS

Various embodiments of an on-vehicle battery system according to the present invention will now be described with reference to the accompanying drawings.

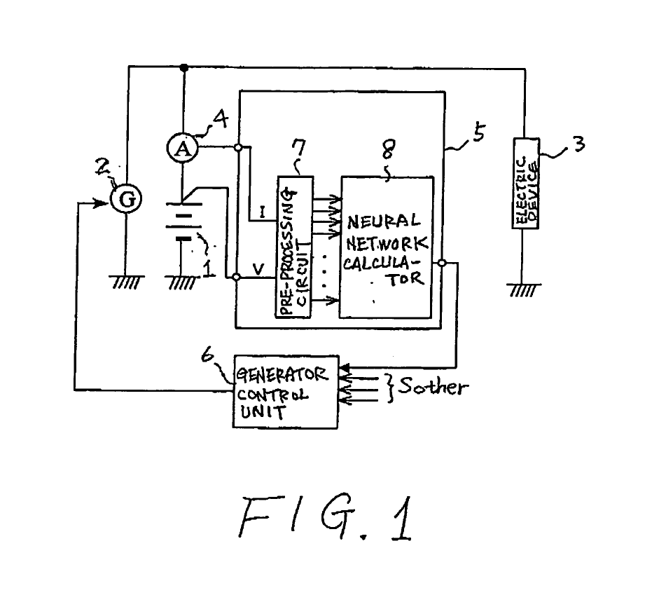

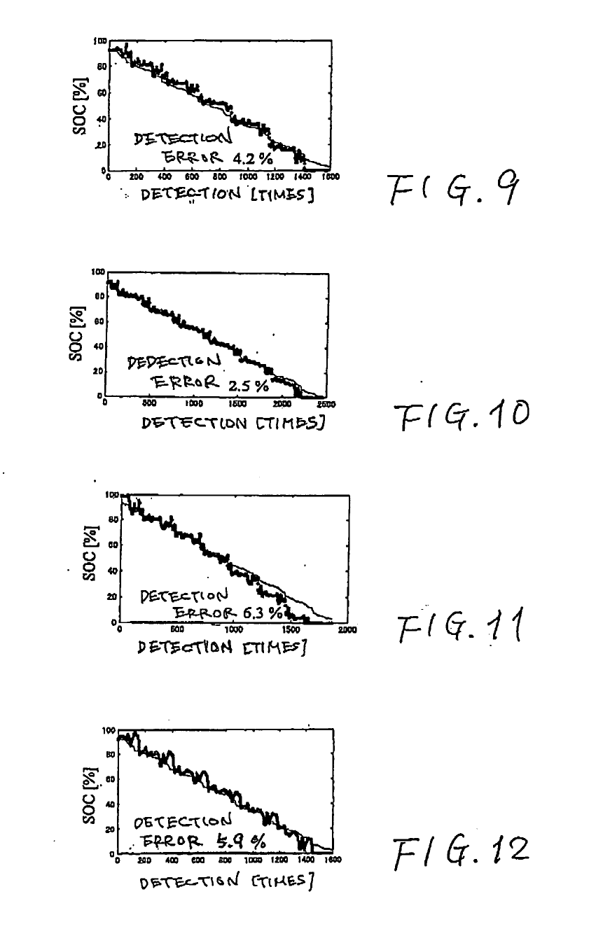

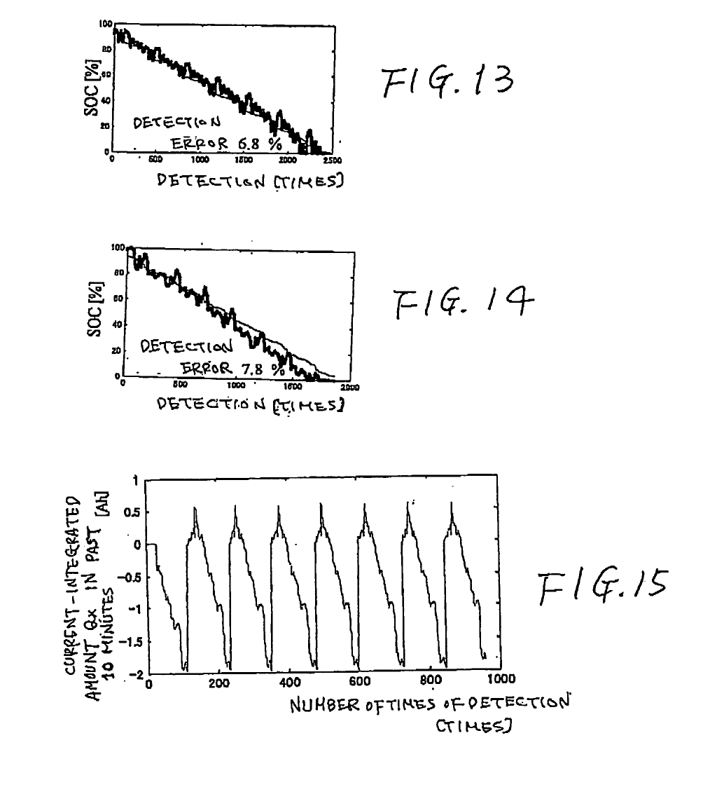

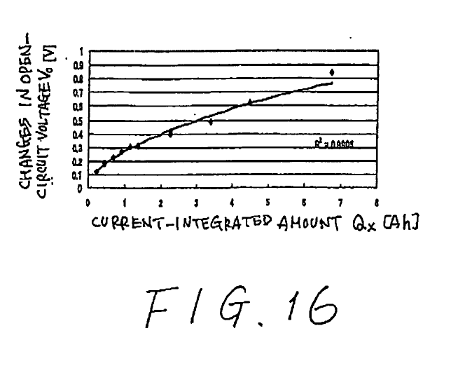

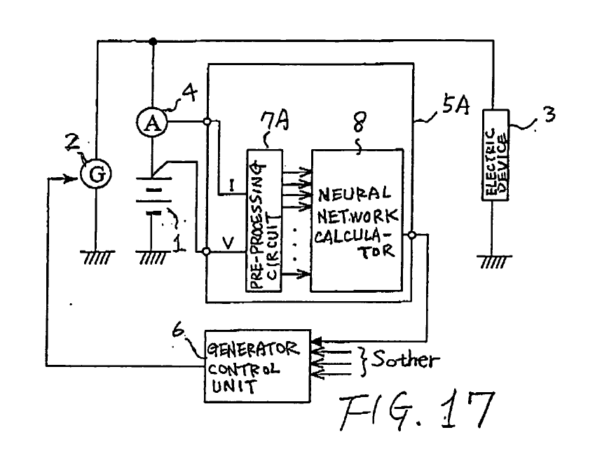

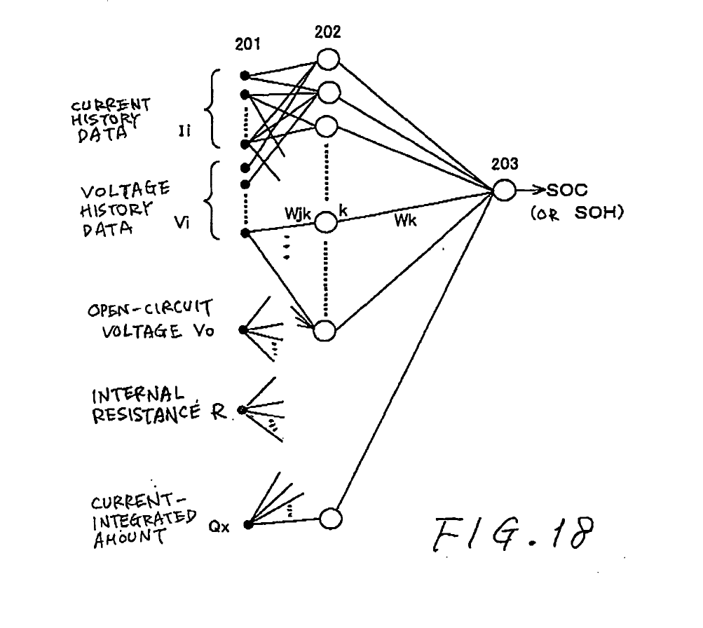

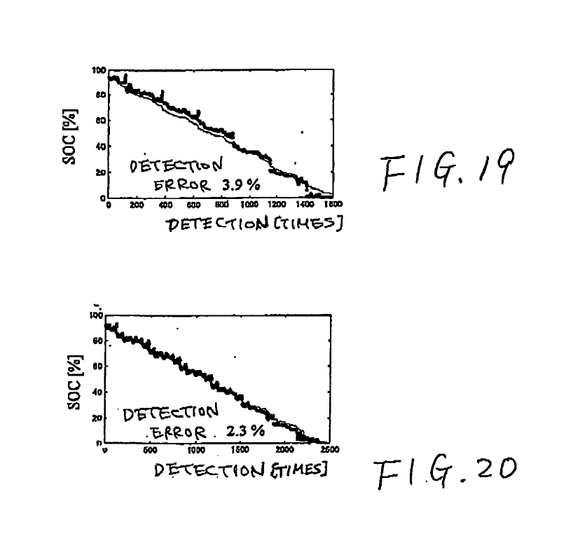

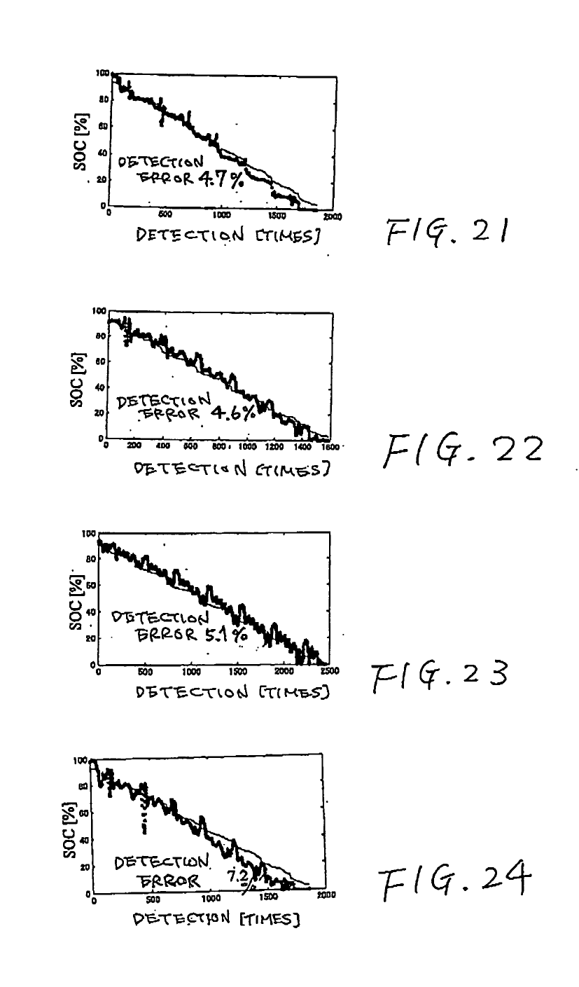

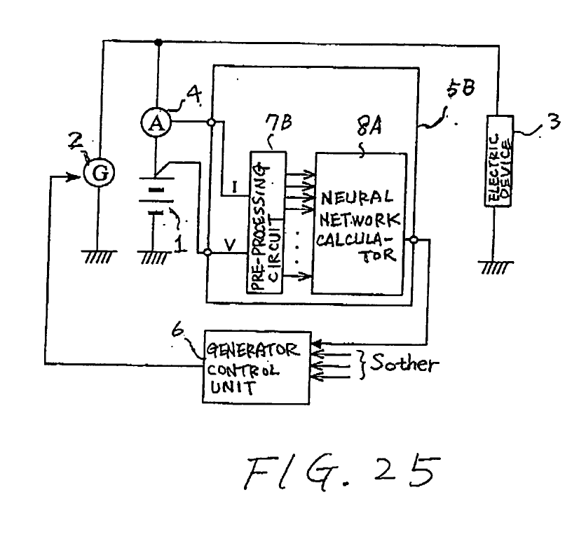

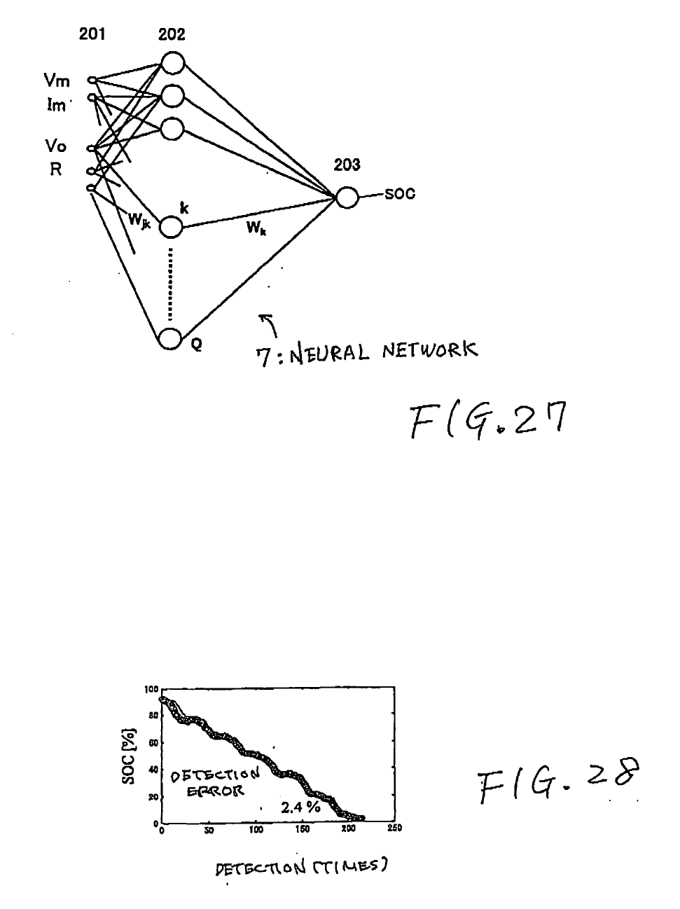

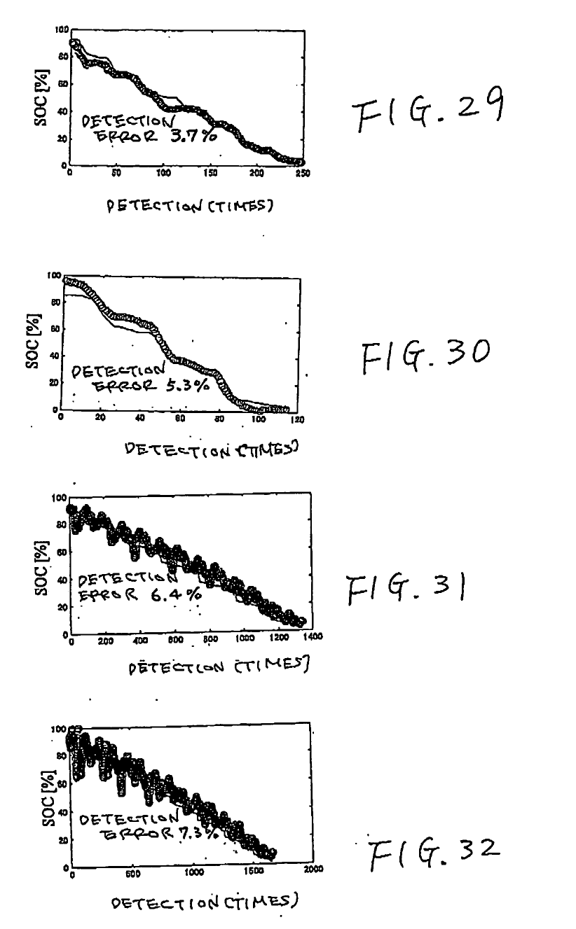

The following embodiments are made up of three embodiments, which are: a first embodiment (including modifications) described in connection with FIGS. 1-16 and 29; a second embodiment (including modifications) described in connection with FIGS. 17-24; and a third embodiment (including modifications) described in connection with FIGS. 25-38.

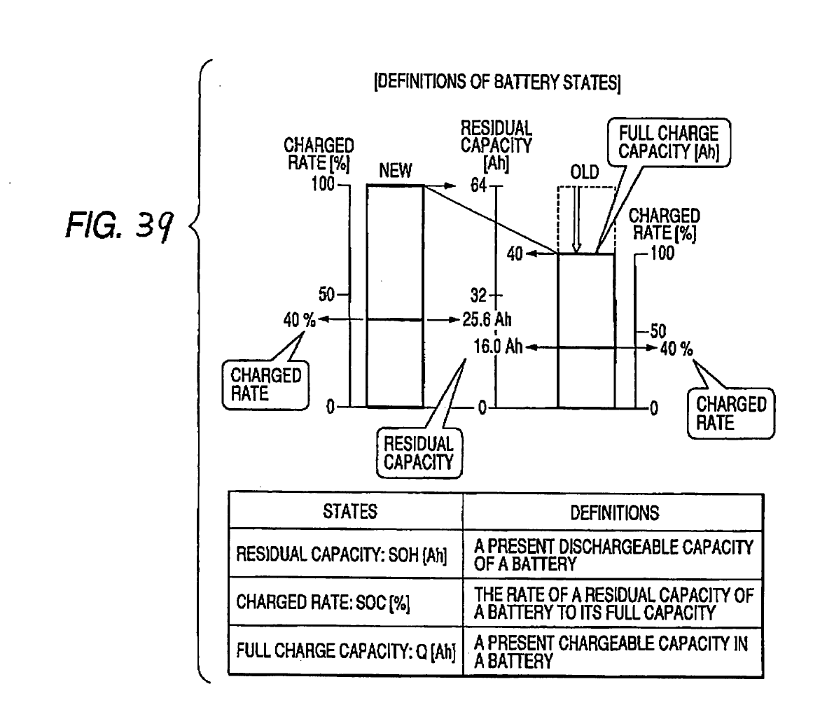

Prior to detailed description of the following embodiments, the charged state of a battery (secondary battery, rechargeable battery) will be defined with reference to FIG. 39. As illustrated, an SOH (state of health) (Ah), called “residual capacity,” means a present dischargeable capacity of a battery, an SOC (state of charge) (%), called “charged rate,” means the rate of a residual capacity of a battery to a full charge capacity thereof, and a full charge capacity Q (Ah) means a present chargeable capacity in a battery. Hence, by way of example, suppose that a new battery which has not been used yet has an SOH of 64 Ah corresponding to an SOC of 100% (i.e., a full charge capacity of 64 Ah). In this battery, an SOH of 25.6 Ah corresponds to an SOC of 40%. And suppose that this new battery has been used and its charging ability is degraded considerably so that a full charge capacity is 40 Ah. However this capacity amount still corresponds to an SOC of 100% and, in this case, an SOC of 40% means an SOH of 16.0 Ah.

### First Embodiment

Referring to FIGS. 1-14, a first embodiment of the on-vehicle battery system will now be described. This on-vehicle battery system is based on neural network type of calculation and corresponds to a battery system according to the present invention.

As shown in FIG. 1, the on-vehicle battery system is provided with an on-vehicle battery (hereinafter, simply referred to as a “battery”) 1 and other electric components including an on-vehicle generator 2, an electric device(s) 3, a current sensor 4, a battery state detector 5, and a generator control unit 6. Of these, as shown, the battery state detector 5 is equipped with a pre-processing circuit 7 and a neural network calculator 8 and may be, in part or as a whole, realized by either calculation on software installed in a dedicated computer system or functions of dedicated digital/analog circuitry.

The on-vehicle generator 2 is mounted on the vehicle to charge the battery 1 and power the electric device 3. The electric device 3 functions as an on-vehicle electric load(s) which is powered by the battery 1 and/or the generator 2. The current sensor 4 is placed between the battery 1 and the electric device 2 to detect charge and discharge currents to and from the battery 1. The battery state detector 5 is an electric circuit unit to detect signals indicating the internal operation (charge/discharge) states of the battery 1. The battery 1 has a terminal connected to the battery state detector 5 to provide its terminal voltage (simply, voltage) to the battery state detector 5.

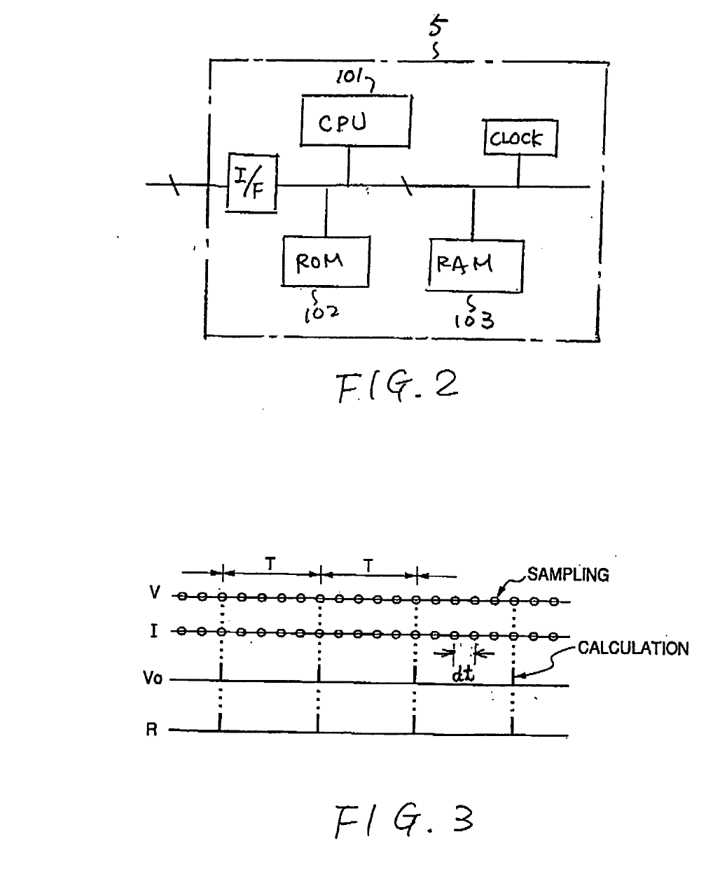

In the present embodiment, the battery state detector 5 is formed by a computer system with a CPU 101 (central processing unit), memories 102 and 103, and other necessary components (refer to FIG. 2). The memories 102 and 103 include a memory 102 in which data of predetermined programs for calculation directed to detecting one or more battery charged states are previously stored. The CPU is able to read the data of the programs whenever it is activated and then perform the calculation on procedures provided by the programs. The performance of the calculation provides the functions of the pre-processing circuit 7 and neural network calculator 8, which will now be detailed, respectively.

From a functional viewpoint, the pre-processing circuit 7 is placed before the neural network calculator 8 and is configured to calculate various input parameters to the neural network calculator 8. Such input parameters include, voltage and current history data Vi and Ii, an open-circuit voltage Vo of the battery 1, and the current-interacted value Qx of the battery 1. The input parameters may additionally include an internal resistance R of the battery 1. The open-circuit voltage Vo is a voltage which appears on the battery terminal, provided that a load current therefrom is regarded as being zero. The current-integrated value Qx represents a polarization-related quantity according to the present invention.

Specifically, the pre-processing circuit 7 applies simultaneous sampling to both data of voltage V from the battery 1 and current I from the current sensor 4 at intervals so that those data V and I can be read in as a pair of data at each sampling time (refer to FIG. 3). Thus a predetermined number of pairs of data each consisting of the voltage V and current I are stored for a predetermined period of time. The predetermined number of paired data of the voltage V and current I acquired during the latest predetermined period of time, which is just before the present calculation to be performed, are provided to the neural network calculator 8 as the voltage and current history data Vi and Ii (serving as part of input parameters) for neural network calculation. Instead of such voltage and current history data Vi and Ii, an average of voltage V of the battery 1 and an average of current I (charging and discharging current) to and from the battery 1, both of which are measured over each of the predetermined periods.

The pre-processing circuit 7 also uses those paired voltage and current history data Vi and Ii to calculate the open-circuit voltage Vo also serving as part of the input parameters for the neural network calculation. In addition, the pre-processing circuit 7 also uses the current history data Ii to calculate the current-integrated value Qx, which represents one polarization-related quantity. This current-integrated value Qx is obtained by integrating the detected currents (charging and discharging currents) over the latest predetermined period (for example, 5 minuses), which is just before the present calculation to be performed. The integration is carried out cyclically every predetermined period.

Incidentally, the internal resistance R can be included in the input parameters to the neural network calculation.

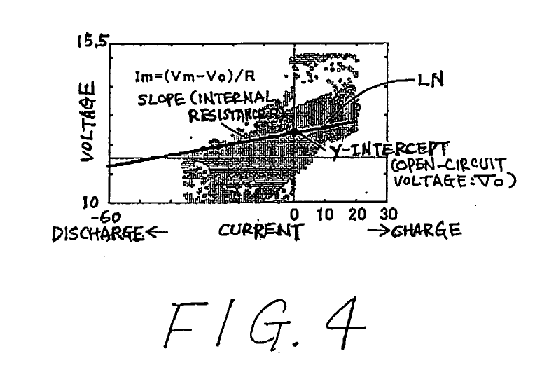

Referring to FIG. 4, how to calculate both the open-circuit voltage Vo and the internal resistance R will now be detailed, which is conducted by the pre-processing circuit 7 as described above.

The pre-processing circuit 7 will now be detailed. The pre-processing circuit 7, samples, simultaneously and at intervals (for example, T/5 seconds and T is 25 seconds; refer to FIG. 3), both the signal of the voltage V of the battery 1 and the signal of current I from the current sensor 4 for memorizing data indicative of the battery voltage history Vi and buttery current history Ii, and also supplies data indicative of voltage V and current I at each time instant to the neural network calculator 8. The sampled data of the voltage V and current I, which compose the battery voltage history Vi and battery current history Ii, is made up of data acquired at respective time instants within a predetermined period of time (e.g., T=25 seconds, refer to FIG. 3) preceding the present time instant. In the present embodiment, by way of example, the voltage history data Vi and current history data Ii are sampled at intervals to produce five data, respectively (refer to FIG. 3), but this is not a definitive list.

In addition to storing the data indicative of the battery voltage history Vi and battery current history Ii, the pre-processing circuit 7 creates data that shows a relationship between the buttery voltage history Vi and the buttery current history Ii and provides the neural network calculator 8 with such relationship data. Such relationship data are created such that the data of both the voltage history Vi and current history Ii are subjected to the least-squares method to compute a linear approximate expression LN showing the relationship between the voltage and current V and I, and the approximate expression LN is subjected to calculation of a y-intercept (corresponding to an open-circuit voltage Vo) and/or slope (corresponding to an internal resistance R) every time when the pairs of voltage V and current I are inputted, whereby a present value of the open-circuit voltage Vo and/or a present value of the internal resistance R are created (refer to FIG. 3). Those present values are able to function as the relationship data between the voltage history Vi and the current history Ii, as described above. How to create the linear approximate expression LN and how to calculate the present value(s) Vo and R based on the approximate expression LN are known, whereby detailed explanations for those are omitted. The least-squares method is helpful in reducing an amount of data to be memorized.

The neural network calculator 8 is configured to receive various types of input parameters (i.e., signals to be inputted) from both the pre-processing circuit 7 and applies neural network calculation to the input parameters so as to output signals indicative of a predetermined storage state quantity (an SOC (state of charge) in the present embodiment). In the present embodiment, as described, the input parameters are the paired voltage and current data Vi and Ii serving as voltage and current history information, the open-circuit voltage Vo, and the current-integrated quantity Qx, all of which are the newest.

The processing steps shown in FIG. 5, which are cooperatively conducted by both the pre-processing circuit 7 and the neural network calculator 8, will now be explained.

In response to the start of the engine, the pre-processing circuit 7 starts its calculation. After the start, both the pre-processing circuit 7 and the neural network calculator 8 reset current values in their working areas (step Si). The pre-processing circuit 7 then detects the voltage V and the current I of the battery 1 at intervals for storage (step S2). Then by the pre-processing circuit 7, a value of the open-circuit voltage Vo is calculated for storage based on the already described way (step S3). This open-circuit value Vo shows a present degraded state quantity of the battery 1.

The pre-processing circuit 7 then calculates the foregoing current-integrated quantity Qx using data acquired over the latest predetermined period (step S4).

Then, all data indicating the voltage and current history data Vi and Ii, open-circuit voltage Vo, and current-integrated quantity Qx are handed to the neural network calculator 8, in which the neural network calculator 8 calculates an SOC (state of charge) of the battery 1, which serves as a physical quantity showing the internal state of the battery 1 (step S5). How to calculate the SOC will now be detailed later. The calculated amount of the SOC is provided from the neural network calculator 8 (step S6).

The generator control unit 6 is placed to control an amount of power to be generated by the on-vehicle generator 2 in response to both of a signal outputted from the neural network calculator 8 and signals Sₒₜₕₑᵣ coming from various other not-shown components.

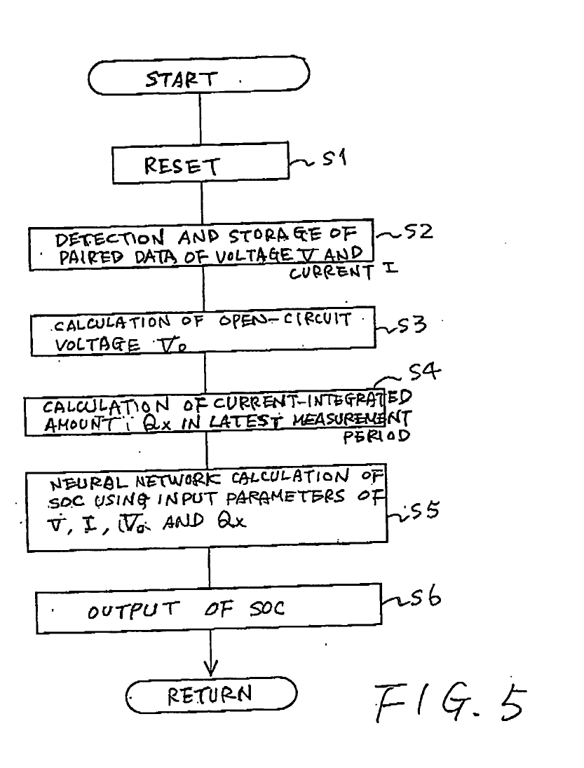

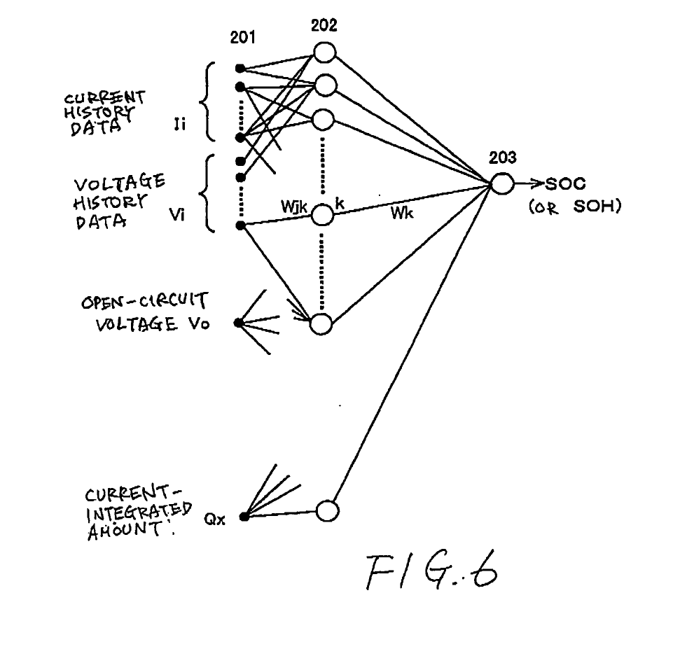

Referring to FIG. 6, the neural network calculator 8 will now be detailed in terms of its functional configuration and its operations. By way of example, the neural network calculator 8 is formed into a three hierarchical feed-forward type of calculator which learns on a back-propagation technique. This type is not decisive, but any neural network type, if selected properly, can be applied to this calculator 8.

The neural network calculator 8 is composed of, as its functional blocks, an input layer 201, an intermediate layer 202, and an output layer 203. Practically, however, this calculator 8 is configured to have a microcomputer system including a CPU and memories and the CPU executes programs read out from a memory, software processing, at intervals given for its calculation.

The input layer 201 is composed of a predetermined number of input sells. The respective input cells not only receive, as input data (signals), voltage history data Vi, current history data Ii, and present values of the open-circuit voltage Vo and internal resistance R from the pre-processing circuit 7 but also receive a value of the open-circuit voltage Vo obtained when the predetermined amount of power is discharged, from the correcting signal generator 9. And the respective input cells hand the received data to all calculation cells belonging to the intermediate layer 202. The calculation cells in the intermediate layer 202 are in charge of applying later-descried neural network calculation to the data to be inputted from the input cells in the input layer 201 and providing resultant calculation results to an output cell in the output layer 203. Since the calculation is directed to an SOC, so that the output cell in the output layer 203 produces as an output data showing the state of charge (SOC).

Provided that data inputted to the j-th cell of the input layer 201 is noted as INj and a coupling coefficient between the j-th cell of the input layer 201 and the k-th cell of the intermediate layer 202 is noted as Wjk, a signal inputted to the k-th cell of the intermediate layer 202 is expressed as
INPUTk(t)=Σ(Wjk*INj) (j=1 to 2m+3) (1).
Further, a signal outputted from the k-th cell of the intermediate layer 202 is expressed as
OUTk(t)=f(x)=f(INPUTk(t)+b) (2),
wherein the reference b is a constant.

The expression (2) is defined by using f(INPUTk(t)+b) which is a non-linear function called sigmoid function which uses INPUTk(t)+b as an input variable. This function is defined such that
f(INPUTk(t)+b)=1/(1+exp(−(INPUTk(t)+b))) (3).
When a coupling coefficient between the k-th cell of the intermediate layer 202 and a cell of the output layer 203 is noted as Wk, an input signal to the output layer 203 is expressed as
INPUTo(t)=ΣWk*OUTk(t) (k=1 to Q) (4),
similarly to the above. The reference Q denotes the number of cells in the intermediate layer 202. Accordingly an output signal from the output layer 203 at a time instant t is
OUT(t)=L*INPUTo(t) (5),
wherein the reference L is a linear constant.

The neural network calculation according to the present embodiment introduces a learning process in which the coupling coefficients of between the cells are optimized so as to minimize errors between a final output OUT(t) at a time t and a previously measured target output (that is, a true value tar(t)) which will described later. The output OUT(t) is an output parameter to be outputted from the output layer 203 and, in the present embodiment, an SOC (state of charge) at a time t.

How to update the coupling coefficients will now be described.

The coupling coefficient Wk between the k-th cell of the intermediate layer 202 and each cell of the output layer 203 is updated based on an expression of
Wk=Wk+ΔWk (6),
in which ΔWk is defined as follows.

$$\begin{matrix}Δ Wk = - η * \partial Ek / \partial Wk \\ = η * [ OUT ( t ) - tar ( t ) ] * [ \partial OUT ( t ) / \partial Wk ] \\ = η * [ OUT ( t ) - tar ( t ) ] * L * [ \partial INPUTo ( t ) / \partial Wk ] \\ = η * L * [ OUT ( t ) - tar ( t ) ] * OUTk ( t ) ,\end{matrix} \qquad ( 7 )$$

wherein η denotes a constant.

The value Ek indicates an error between the teaching data and a network output and can be defined as follows:
Ek=[OUT(t)−tar(t)]*[OUT(t)−tar(t)]/2 (8).

Further, how to update the coupling coefficient Wjk between the k-th cell of the intermediate layer 202 and the j-th cell of the input layer 201 will now be described. The coupling coefficient Wjk is updated on an expression of
Wjk=Wjk+ΔWjk (9),
in which ΔWjk is defined as follows:

$$\begin{matrix}Δ Wjk = - η * \partial Ek / \partial Wjk \\ = - η * [ \partial Ek / \partial INPUTk ( t ) ] * [ \partial INPUTk ( t ) / \partial Wjk ] \\ = - η * [ \partial Ek / \partial OUTk ( t ) ] * \{ \partial OUTk ( t ) / \partial INPUTk ( t ) ] * INj \\ = - η * [ \partial Ek / \partial OUT ( t ) ] * [ \partial OUT ( t ) / \partial INPUTo ] * \\ [ \partial INPUTo / OUTk ( t ) ] * {f}^{′} ( INPUTk ( t ) + b ) * INj \\ = - η * ( OUT ( t ) - tar ( t ) ) * L * Wk * {f}^{′} ( INPUTk ( t ) + b ) * INj \\ = - η * L * Wk * INj * ( OUTsoc ( t ) - tar ( t ) ) * {f}^{′} ( INPUTk ( t ) + b ) ,\end{matrix} \qquad ( 10 )$$

in which f′(INPUTk(t)+b) is a derivative value of a transfer function.

The thus-updated new coupling coefficients Wk and Wjk are used to re-calculate an output OUT(t), that is, an SOC at a time t. This update and calculation process will be repeated until the error function Ek becomes below a given minute value. Hence, a process in which the coupling coefficients are updated to bring the error function Ek into a value below the given minute value is the foregoing learning process.

Referring to FIG. 7, a flowchart showing the foregoing learning process will now be described. In this process, a target to be outputted from the neural network calculator 8 is a quantity indicating the state of the battery 1 (i.e., charged state quantity). Practically, for example, the charged state quantity is an SOC (state of charge). Alternatively, the charged state quantity may be an SOH (state of health).

First, when the start is commanded, the neural network calculator 8 gives properly selected initial values to the coupling coefficients (step S11). The initial values are decided by using a random table, for example. Then the calculator 8 reads in, as input signals, the foregoing input signals for learning and receives at each cell of the input layer 201 (step S12). Using the foregoing initial values given to the coupling coefficient, the input signals are subjected to the neural network calculation so that a value of the SOC, i.e., the output parameter, is figured out (step S13).

The calculator 8 then calculates the error function Ek according to the foregoing expression (step S14) and determines whether or not the error function Ek represents a value smaller than a threshold “th” serving as a given minute value (step S15). In cases where the value of the error function Ek is equal to or more than the threshold th, the calculator 8 allows the coupling coefficients Wk and Wjk to be subjected to the update so as to figure out update amounts ΔW, which are defined as above in the learning process (step S16), and then proceeds to the update of the coupling coefficients Wk and Wjk (step S17).

The processing in the neural network calculator 8 is then returned to step S12 to read again the input signals for learning at the cells of the input layer 201. Hence the SOC is calculated again as the above and repeat the foregoing processing until the error function Ek has a value smaller than the threshold th.

In contrast, when the calculator 8 determines that the error function Ek presents a value smaller than the threshold “th,” the calculator 8 decides that the learning has been completed (step S18). In response to this decision, the learning process is ended.

Accordingly, the neural network calculator 8 can be manufactured such that the calculator 8 previously learns several charge/discharge patterns corresponding to representative battery types based on the foregoing learning process before shipment of the products. Thus each vehicle is able to estimates, with precision, by the use of the neural network calculation, the SOC of the battery in the actual running, independently of fluctuations in manufacturing of batteries to be mounted on respective vehicles.

(Test Results)

Five batteries, whose capacities and degraded states are different from each other as listed in FIG. 8, were actually prepared and subjected to measurement of charge/discharge currents and terminal voltages of those batteries during the run under the 10.15 running mode. An open-circuit voltage Vo and an current-integrated value Qx in the latest determined integration period, which are for neural network calculation, were calculated as input parameters, and then these input parameters and a previously calculated true value of the SOC (to be calculated from the current integrated quantity Qx) are used as teaching signals for the learning.

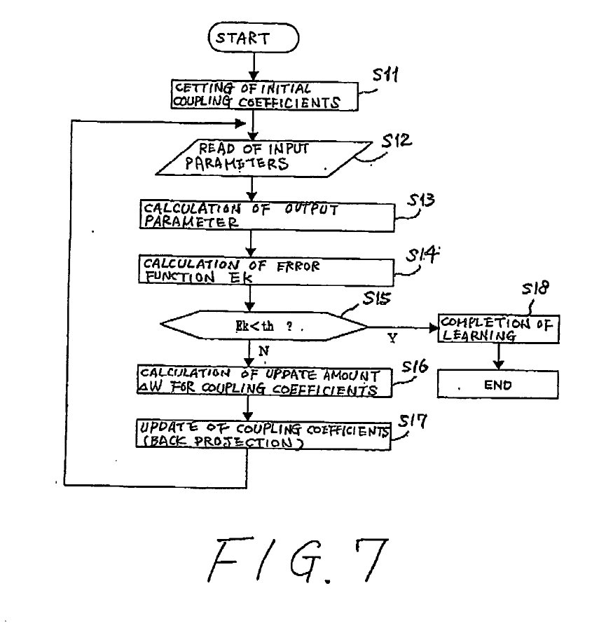

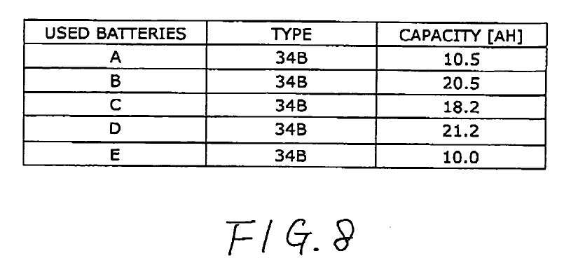

In the next place, the thus-learned neural network was used to calculate the values of SOC of three new degraded batteries (i.e. used batteries). The SOC values were thus subjected to the comparison with the true values of SOC calculated on the current integration method, of which comparison results are shown in FIGS. 9-14. Of these graphs, FIGS. 9-11 show the SOC results of the three test batteries, which are resultant from the calculation of the foregoing input parameters including the current-integrated quantity Qx, that is, using the voltage and current history data Vi and Ii, the open-circuit voltage Vo, and the current-integrated quantity Qx. In contrast, FIGS. 12-14 show the SOC results of the same three test batteries, which are resultant from the calculation of the input parameters excluding the current-integrated quantity Qx, that is, using only the voltage and current history data Vi and Ii and the open-circuit voltage Vo. FIG. 15 shows the waveform of the latest current-integrated quantity Qx used for the comparison. From the comparison between FIGS. 9-11 and FIGS. 12-14, it has been found that only adding the current-integrated quantity Qx to the input parameters is able to raise the precision in calculating the SOC.

Moreover, the foregoing test batteries were subjected to the examination of a correlation between changes in the open-circuit voltage Vo and the current-integrated quantity Qx obtained from the latest integration period used to calculate the open-circuit voltage Vo. The state of polarization is reflected in the changes in the open-circuit voltage Vo. The resultant correlation is shown in FIG. 16, which shows that the changes in the open-circuit voltage Vo correlate highly with the current-integrated quantity Qx. As a result, by including into the input parameters both the open-circuit voltage Vo and the current-integrated quantity Qx obtained in the latest integration period used to calculate the voltage Vo, not including only the open-circuit voltage Vo, it can be estimated that the latest current-integrated quantity Qx included in the open-circuit voltage Vo (specifically, the influence of the polarization) is reduced.

As described above, in the present embodiment only one input parameter, which is current-integrated quantity Qx strongly related to the polarization index, is added to the existing input parameters. This addition enables a polarization component in the voltage to be cancelled through the neural network calculation. It is therefore possible to detect the output parameter indicating a charged state of the battery with precision, while still suppressing increases in the calculation load and circuitry.

As shown in the present embodiment, it is preferred to employ, as voltage and current information, voltage/current paired history data acquired during the latest calculation period and to employ the open-circuit voltage Vo of the battery 1 as one input parameter relating to degradation of the battery 1. This allows a decrease in precision in calculating the battery charged state to be suppressed independently of fluctuations of battery degradation. Moreover, the steps of calculation of the open-circuit voltage Vo can be made with less influence of the polarization-related quantity to be caused in the calculation. This further improves the precision in calculating the charged state of the battery 1.

More specifically, in the present embodiment, in the same way as the above, the open-circuit voltage Vo is approximated based on voltage/current data acquired in the past. A dischargeable amount of the secondary battery is changed depending on how degree the degradation advances in the battery, and the degradation degree relates to the open-circuit voltage Vo. Hence, for considering the influence of the degraded degree in calculating the charged state, it is preferred to add the open-circuit voltage Vo to the input parameters for the neural network calculation. Based on this, the input parameters include voltage and current data, an open-circuit voltage Vo serving as a component relating to degraded states of the battery (such component is included in those voltage and current), and the polarization-related quantity to the polarization whose amount is included in those voltage V and open-circuit voltage Vo. Hence, a correlation between the voltage/current and the charged state amount can be extracted through the neural network calculation, in which the voltage and current are provided as amounts whose battery degradation component and the polarization component are mutually cancelled out. This improves the accuracy in the neural network calculation.

### Second Embodiment

Referring to FIGS. 17-25, a second embodiment of the on-vehicle battery system will now be described.

For the sake of a more simplified explanation, the identical or similar components to those in the first embodiment will be given the same reference numbers in the present second embodiment and succeeding embodiments.

The second embodiment is based on the fact that an internal resistance R of the battery 1 has also a high correlation with the current-integrated quantity Qx. Thus, both the internal resistance R and the current-integrated quantity Qx obtained in the latest calculation (measurement) period are combinedly introduced in the input protesters, so that a component of the latest current-integrated quantity Qx, which is included in the internal resistance R, can be reduced, that is, the influence of the polarization is reduced.

Practically, as shown in FIG. 17, in the second embodiment, the on-vehicle battery system is provided with a battery state detector 5A including a pre-processing circuit 7A which has the capability of calculating the internal resistance R of the battery 1, which is added to the input parameters to the neural network calculator 8. How to calculate the internal resistance R has been described already (refer to FIG. 4). Hence, as shown in FIG. 18, the neural network calculator 8 is configured to perform the neural network calculation on the basis of the input parameters including the internal resistance R of the battery 1.

(Test Results)

The five batteries, whose capacities and degraded states are different from each other as listed in FIG. 8, were actually prepared and subjected to measurement of charge/discharge currents and terminal voltages of those batteries during the run under the 10.15 running mode. An open-circuit voltage Vo, an internal resistance R and an current-integrated value Qx in the latest determined integration period, which are all for neural network calculation, were calculated as input parameters, and then these input parameters and a previously calculated true value of the SOC (to be calculated from the current integrated quantity Qx) are used as teaching signals for the learning.

In the next place, the thus-learned neural network was used to calculate the values of SOC of three new degraded batteries (i.e. used batteries). The SOC values were thus subjected to the comparison with the true values of SOC calculated on the current integration method, of which comparison results are shown in FIGS. 19-24. Of these graphs, FIGS. 19-21 show the SOC results of the three test batteries, which are resultant from the calculation of the foregoing input parameters including the current-integrated quantity Qx, that is, using the voltage and current history data Vi and Ii, the open-circuit voltage Vo, the internal resistance R, and the current-integrated quantity Qx. In contrast, FIGS. 22-24 show the SOC results of the same three test batteries, which are resultant from the calculation of the input parameters excluding the current-integrated quantity Qx, that is, using only the voltage and current history data Vi and Ii, the open-circuit voltage Vo and the internal resistance R. The waveform of this latest current-integrated quantity Qx used for the comparison is also shown in FIG. 16. From the comparison between FIGS. 19-21 and FIGS. 22-24, it has been found that only adding the current-integrated quantity Qx to the input parameters is able to raise the precision in calculating the SOC.

In the present embodiment, the internal resistance R is also taken in as an input parameter relating to an amount of the degradation of the battery 1. This is based on the consideration that the calculation of the internal resistance R involves a component affected by the polarization, resulting in that the internal resistance R has a correlation with the polarization. Therefore, as shown in the present embodiment, employing the polarization-related amount as an input parameter is effective for canceling out the polarization-correlated component of the internal resistance R. This also improves the neural network calculation, providing the similar advantages to those in the first embodiment.

### (Third Embodiment)

Referring to FIGS. 25-38, a third embodiment of the on-vehicle battery system will now be described.

As shown in FIG. 24, the on-vehicle battery system of the present embodiment is provided with a battery state detector 5B functionally having a pre-processing circuit 7B and a neural network calculator 8A. The remaining circuitry of this on-vehicle battery system is identical to that in the first embodiment.

The pre-processing circuit 7B is configured to simultaneously sample, as paired data, at every given sampling interval dt (refer to FIG. 3), both the signal of voltage (terminal voltage) of the battery 1 and the signal of current (charge/discharge current) taken by the current sensor 4 for their storage. Using a predetermined number of paired voltage and current data which have been acquired during the latest predetermined measurement period of time for memorization (the data include currently sampled paired data of the voltage and current), the pre-processing circuit 7B calculates both a voltage average Vm of data of the voltage V and a current average Im of data of the current I. Moreover, the pre-processing circuit 7B has the capability of using data of the currently acquired current to calculate a polarization index Pn which is defined as the polarization-related quantity according to the present invention.

Thus, the input parameters in the present embodiment are the voltage average Vm, current average Im, open-circuit voltage Vo, and internal resistance R. With no use of the paired voltage/current history data (i.e., a large number of data) that leads to an increase in the neural network calculation amount, the SOC can be calculated with precision.

The polarization index Pₙ will now be detailed.

The polarization index Pₙ can be formulated as “Pₙ₋₁+ΔP1−ΔP2,” wherein Pₙ₋₁ denotes the last polarization index calculated at the last sampling timing, which shows a residual value of the polarization index Pn), ΔP1 denotes an increased amount of the polarization index, which is caused in the sampling interval dt from the last sampling to the present sampling, and ΔP2 denotes a decay (decreased) amount of the polarization index, which is caused in the sampling interval from the last sampling to the present sampling. The polarization index Pn calculated at the present calculation timing is memorized together with the presently detected data of the voltage V and current I in the form of one set of data.

In the present embodiment, the increased amount ΔP1 is defined as a value produced by multiply the value of the preset current I by the sampling interval dt starting from the last sampling to the present sampling. In other words, the increased amount ΔP1 essentially equals a current-integrated value calculated over each sampling period dt. The current-integrated value is a quantity of electric charge which can be regarded as being proportional to a quantity of polarization.

Meanwhile, the decayed amount ΔP2 is calculated on a formula “(1/τ)·Pₙ₋₁·dt,” wherein X is an attenuation time constant of the polarization. That is, it can be stated that the polarization is decayed by an amount decided by 1/τ, every unit time dt. Since the decay time constant τ in charging the battery 1 differs from that in discharging from the battery 1, the decay time constant X should be differentiated depending on whether the presently detected current I is a charge current or a discharge current. Specifically, when the presently detected current I shows the charge current, a time constant rp is employed for the decay time constant τ, whilst when the presently detected current I shows the discharge current, a time constant Ed is employed for the decay time constant τ. In the end, the polarization index Pₙ, which is almost proportional to the present polarized quantity, can be expressed by the following formula:
Pₙ=Pₙ₋₁+I·dt−(1/τ)·Pₙ₋₁·dt,

wherein τ=τₚ (in the charge state) and
τ=τ_{d} (in the discharge state).

Using FIG. 25, the processing carried out cooperatively by both the pre-processing circuit 7B and the neural network calculator 8A will now be described.

In response to the start of the engine, the pre-processing circuit 7B starts its calculation. After the start, both the pre-processing circuit 7B and the neural network calculator 8A perform initial setting by resetting present values in their working areas (step S11). The pre-processing circuit 7B then detects the voltage V and the current I of the battery 1 at intervals for storage in its memory (step S12). Then, the pre-processing circuit 7B calculates an average Vm of the values of the voltage V detected at intervals and an average Im of the values of the current I detected at intervals (step S13).

Then, by the pre-processing circuit 7B, the foregoing polarization index Pn is calculated and stored in its memory, as described (step S14). And the pre-processing circuit 7B searches the memory for all pairs of data consisting of, pair by pair, values of both the voltage V and the current I (step S15), both the voltage V and current I being memorized in the memory so as to form one set of data together with a polarization index whose amount is approximately equal to the amount of the presently calculated polarization index Pₙ at step S14. In the present embodiment, such pairs of voltage V and current I are called “equi-polarization voltage/current paired data.”

Using those read-out equi-polarization voltage/current paired data,” both an open-circuit voltage Vo and an internal resistance R are calculated by the pre-processing circuit 7B (step S16). Since the data of the voltage V and current I included in the equi-polarization voltage/current paired data” are mapped two-dimensionally in the same way as FIG. 3 in the first embodiment, the open-circuit voltage Vo and the internal resistance R are calculated in the same way as that descried in the first embodiment.

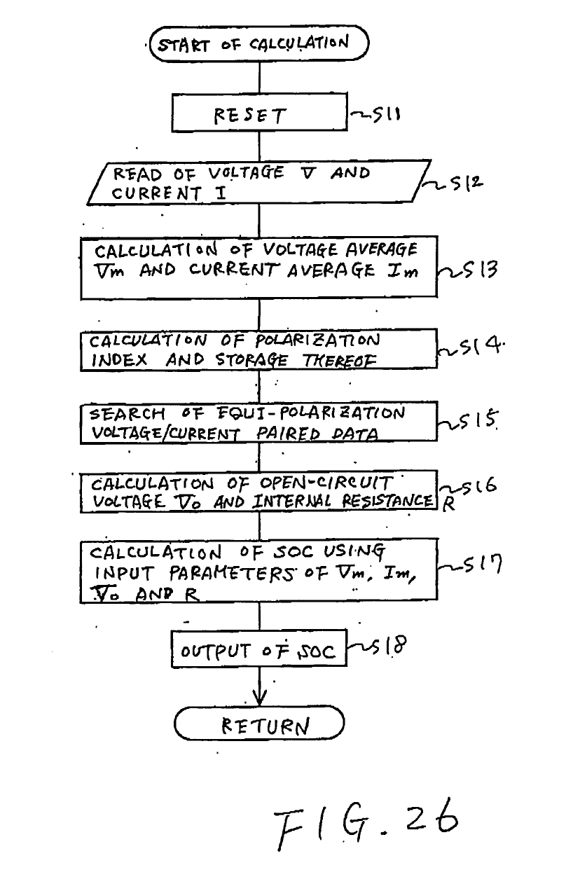

The resultant input parameters consisting of the voltage average Vm, current average Im, open-circuit voltage Vo and internal resistance R are provided from the pre-processing circuit 7B to the neural network calculator 8A, as explained in FIG. 27. Hence, in the present embodiment, in order to obtain an SOC, the neural network calculator 8A is configured to perform the neural network calculation in the same way as that described in the first embodiment. Of course, the input parameters may include other appropriately selected parameters. In addition, other output parameters, such as SOH, may be adopted in place of the SOC or together with the SOC.

(Test Results)

Five batteries, whose capacities and degraded states are different from each other as listed in FIG. 8 described, were actually prepared and subjected to measurement of charge/discharge currents and terminal voltages of those batteries during the run under the 10.15 running mode. The foregoing four input parameters (i.e., the voltage average Vm, current average Im, open-circuit voltage Vo and internal resistance R) are calculated, and then these input parameters and a previously calculated true value of the SOC (to be calculated from the current integrated quantity Qx) are used as teaching signals for the learning.

In the next place, the thus-learned neural network was used to calculate the values of SOC of three new degraded batteries (i.e. used batteries). The SOC values were thus subjected to comparison with the true values of SOC calculated on the current integration method, of which comparison results are shown in FIGS. 28-33. Of these graphs, FIGS. 28-30 show the SOC results of the three test batteries, which are resultant from the calculation of the foregoing input parameters, which include the open-circuit voltage Vo and the internal resistance R both of which were subjected to the correction based on the polarization index. In contrast, FIGS. 31-33 show the SOC results of the same three test batteries, which are resultant from the calculation of the input parameters including the open-circuit voltage Vo and the internal resistance R both of which were not subjected to such correction. From the comparison between FIGS. 28-30 and FIGS. 31-33, it has been found that the correction based on the polarization index, that is, to use the open-circuit voltage Vo and the internal resistance R which were corrected in terms of the polarization, is able to raise the precision in calculating the SOC.

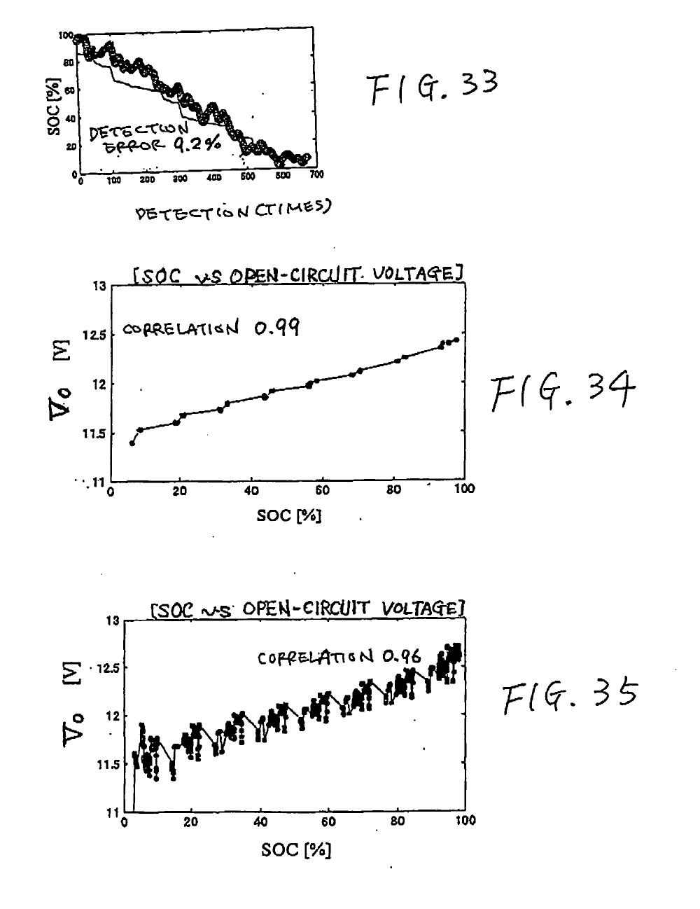

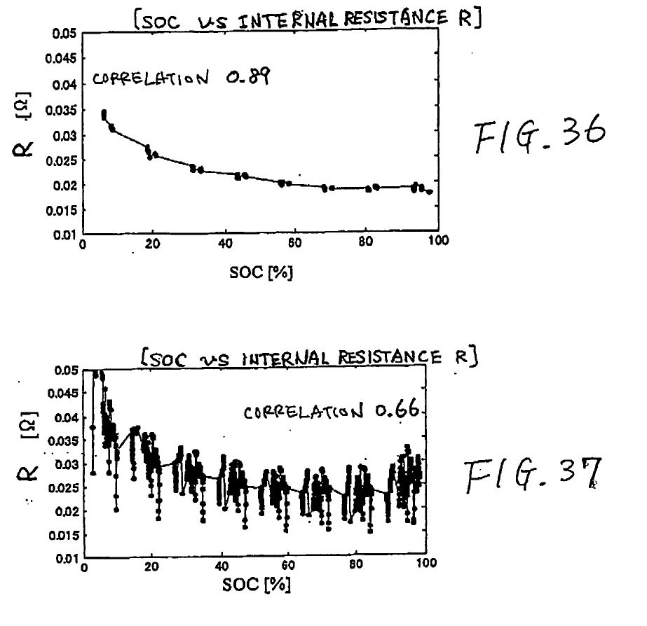

FIGS. 34 and 36 show correlations between the SOC and the open-circuit voltage Vo and between the SOC and the internal resistance R, respectively, which were obtained in the measurement for the results shown FIG. 28. Similarly, FIGS. 35 and 37 show correlations between the SOC and the open-circuit voltage Vo and between the SOC and the internal resistance R, respectively, which were obtained in the measurement for the results in FIG. 31.

To be specific, FIG. 34 represents the correlation between the SOC and the open-circuit voltage Vo calculated on the “equi-polarization voltage/current paired data” depending on the polarization index Pn. It was found that the correlation is as high as 0.99. By contrast, FIG. 35 represents the correlation between the SOC and the open-circuit voltage Vo calculated on the “mere voltage/current paired data” with no consideration of the polarization index Pₙ. It was found that the correlation is 0.96. FIG. 36 represents the correlation between the SOC and the internal resistance R calculated on the “equi-polarization voltage/current paired data” depending on the polarization index Pn. It was found that the correlation is as high as 0.89. By contrast, FIG. 37 represents the correlation between the SOC and the internal resistance R calculated on the “mere voltage/current paired data” with no consideration of the polarization index Pₙ. It was found that the correlation is 0.66, which is considerably low.

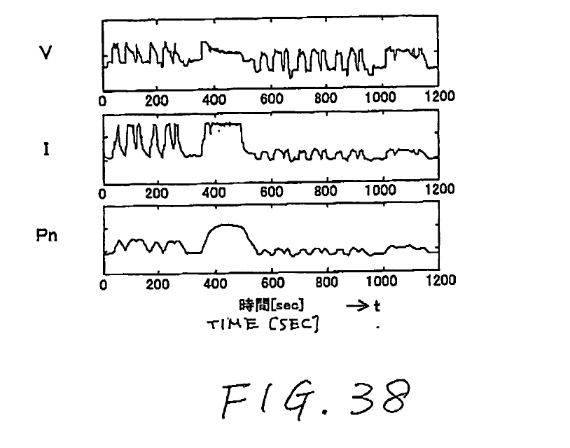

For reference, FIG. 38 shows temporal changes in the polarization index Pₙ obtained in the measurement for the results in FIG. 28.

Accordingly, in the present embodiment, the open-circuit voltage Vo and the internal resistance R are avoided from being influenced by the polarization. By using, as part of the input parameters, the open-circuit voltage Vo and internal resistance R which has already been almost released from the influence of the polarization, the neural network calculation can be made with higher precision. In addition to being less delay of the calculation, because the number of input parameters is not changed at all.

Moreover, the open-circuit voltage Vo and/or the internal resistance R both serving as factors relating to the battery charged state and the battery degraded state, respectively, are used as part of the input parameter, information indicating the charged state can be calculated precisely even if the battery 1 to be detected is degraded differently from other batteries. And, the open-voltage battery Vo can be calculated with less influence of the polarization, improving in calculating the battery charged state. In addition, with the use of the voltage and current data in which the influences of both the degradation and the polarization are canceled out with each other, a correlation of the voltage and current with the charged state amount can be extracted as an output parameter by the neural network calculation.

In addition, in the present embodiment, the equi-polarization voltage/current paired data” that correspond to a value of the polarization-related quantity are read out and used for the calculation of the open-circuit voltage Vo and internal resistance R. Hence it is possible to calculate the values Vo and R using the paired data which are mutually equally influenced by the polarization. With a difficulty to handle complex relationships between the amount of polarization and the open-circuit voltage Vo and internal resistance R, the open-circuit voltage Vo and internal resistance R with less influenced by the polarization can be fed to the neural network, leading to calculating the output parameter of a higher precision.

In the present embodiment, the polarization-related quantity, that is, the polarization index Pn, is designated as an amount of current integrated over the latest predetermined period of time. This is based on the fact that the amount of polarization in the battery 1 has a higher correlation with an integrated amount of charge/discharge current occurring during a short period of time, such as 5-10 minutes, which is just before the present calculation to be performed. Accordingly, the latest current-integrated quantity can be represented as the polarization-related quantity.

As an alternative, the polarization-related quantity may be an amount obtained by integrating “k·I” over a predetermined period of time which is just before the present calculation to be performed, in which k is a weighting coefficient which becomes smaller as the time elapses. This integrated value is called “time-decay-weighted current-integrated value.” Because the polarization decays as the time elapses, the decay factor can be regarded as the foregoing weighting coefficient. Furthermore, the decay factor of the polarization (i.e., polarization decay time constant) differs between the charge and the discharge. Thus weighting coefficients which differently provide decay factors becoming smaller in time can be provided in both the charge and discharge states.

The configuration of the third embodiment can be modified such that only one of the open-circuit voltage Vo and the internal resistance R is subjected to the correction on the polarization index Pₙ, not limited to a configuration where both the open-circuit voltage Vo and the internal resistance R are subjected to such correction. This modification is still effective in raising the accuracy for estimating the SOC and/or SOH.

In addition, the “equi-polarization voltage/current paired data” are not always limited to those providing almost (substantially) equal polarization indices. Instead, the “equi-polarization voltage/current paired data” may be data providing different polarization indices, as long as the change rates between the polarization index Pₙ and the open-circuit voltage Vo and/or internal resistance R are previously memorized for correction of the open-circuit voltage Vo and/or internal resistance R. That is, the open-circuit voltage Vo and/or internal resistance R obtained from voltage/current paired data which exclude the influence of the polarization index can be corrected based on the memorized changed rates. Similarly, the relationships between the polarization index and the voltage/current paired data can be memorized in advance. Such relationships can be used for correcting voltage and current data detected from a secondary battery in terms of the polarization index and then producing input parameters to be fed to the neural network. Further such relationships may be used for calculation of the open-circuit voltage Vo and/or internal resistance R.

The first to third embodiments can be modified further. For example, it is preferred that the terminal voltage (simply, voltage) of the secondary battery and the charge/discharge current (simply, current) to/from the secondary battery are subjected to noise reduction processing, such as low-pass filtering to cut noise components and extract a DC component or low-frequency components and calculation of an average over the last predetermined measurement period of time.

A further modification is provided, in which the voltage V and the open-circuit voltage Vo may include a linearly converted function thereof, respectively. By way of example, suppose that K1 and K2 are constants. In that case, “K1·V+K2” and/or “KitVo+K2” may be used.

An output error between the input parameter V (Vo) and the input parameter “K1·V+K2” (“K1·Vo+K2”) can be converged readily through the neural network calculation.

Further, the voltage V, open-circuit voltage Vo, and internal resistance R may be expressed by relative values to those values obtained when the battery is fully charged. Those relative values are called “full charge ratios.” Each of the “full charge ratio” is defined as a ratio of a present value of each physical quantity to a value thereof obtained in the fully charged state of the battery 1. The full charge ratio for the voltage V is a ratio of Vp/Vf, in which Vp denotes a present value of the voltage V and Vf denotes a fully charged voltage; the full charge ratio for the open-circuit voltage Vo is a ratio of Vop/Vof, in which Vop denotes a present value of the open-circuit voltage V and Vof denotes a value of the open-circuit voltage Vo gained when the battery is fully charged; and the full charge ratio for the internal resistance R is a ratio of Rp/Rf, in which Rp denotes a present value of the resistance R and Rf denotes a value of the resistance R gained when the battery is fully charged. The full charge ratios make it easier and proper to make a comparison among different batteries, leading to an improvement in the detecting precision.

The present invention may be embodied in several other forms without departing from the spirit thereof. The embodiments and modifications described so far are therefore intended to be only illustrative and not restrictive, since the scope of the invention is defined by the appended claims rather than by the description preceding them. All changes that fall within the metes and bounds of the claims, or equivalents of such metes and bounds, are therefore intended to be embraced by the claims.

What is claimed is:

1. A neural network type of apparatus for detecting an internal state of a secondary battery implemented in a battery system, the apparatus comprising:
detecting means for detecting electric signals indicating an operating state of the battery; and
calculating means for calculating, using the electric signals, information indicating the internal state of the battery on the basis of neural network calculation, the information reflecting a reduction in an effect of polarization of the secondary battery.

2. The apparatus according to claim 1, wherein the calculating means includes
producing means for producing, using the electric signals, an input parameter required for calculating the internal state of the battery, the input parameter including i) a polarization-related quantity relating to a charge and discharge current flowing during a latest predetermined period of time which affecting an amount of polarization of the secondary battery and ii) data indicating a voltage of a the secondary battery and a current from and to the secondary battery; and
estimating means for estimating an output parameter serving as the information indicating the internal state of the battery by applying the input parameter to the neural network calculation.

3. The apparatus according to claim 2, wherein the data indicating the voltage and the current of the input parameter include voltage history data, current history data, and an open-circuit voltage of the secondly battery.

4. The apparatus according to claim 3, wherein the polarization-related quantity is an integrated value of current obtained by integrating the current during the latest predetermined period of time.

5. The apparatus according to claim 4, wherein the polarization-related quantity is a value obtained by performing an integration of “k·I”, wherein I denotes the current and k denotes a weighting coefficient which becomes smaller as time passes from a current time instant.

6. The apparatus according to claim 2, wherein the polarization-related quantity is an integrated value of current obtained by integrating the current during the latest predetermined period of time.

7. The apparatus according to claim 2, wherein the polarization-related quantity is a value obtained by performing an integration of “k·I”, wherein I denotes the current and k denotes a weighting coefficient which becomes smaller as time passes from a current time instant.

8. The apparatus according to claim 3, wherein the polarization-related quantity is a value obtained by performing an integration of “k·I”, wherein I denotes the current and k denotes a weighting coefficient which becomes smaller as time passes from a current time instant.

9. The apparatus according to claim 1, wherein the calculating means includes
producing means for producing, using the electric signals, an input parameter required for calculating the internal state of the battery, the input parameter including a functional value correlating to the internal state of the secondary battery, the functional value reflecting the reduction in an effect of polarization of the secondary battery; and
estimating means for estimating an output parameter serving as the information indicating the internal state of the battery by applying the input parameter to the neural network calculation.

10. The apparatus according to claim 9, wherein the producing means includes polarization-related value calculating means for calculating a polarization-related value having a positive correlation with an amount of polarization caused in the secondary battery and correcting means for correcting the functional value based on the polarization-related value.

11. The apparatus according to claim 10, wherein the polarization-related value is a polarization index showing an amount of the polarization

12. The apparatus according to claim 11, wherein the functional value is composed of at least one of an open-circuit voltage and an internal resistance of the secondary battery.

13. The apparatus according to claim 10, wherein the polarization-related value is a polarization index showing an amount of the polarization and the input parameter is composed of an average of voltages of the secondary battery, an average of currents to and from the secondary battery, and the functional value, the functional value being composed of an open-circuit voltage of the secondary battery and an internal resistance of the secondary battery, the averages being measured over a latest predetermined measurement period of time.

14. The apparatus according to claim 13, wherein the correcting means is configured to acquire plural pairs of data each consisting of the voltage and the current, the plural pairs of data respectively providing amounts of the polarization index which are approximately equal to each other, and to correct at least one of the open-circuit voltage and the internal resistance based on the plural pairs of data each consisting of the voltage and the current.

15. A method of detecting an internal state of a secondary battery implemented in a battery system, comprising steps of:
detecting electric signals indicating an operating state of the battery; and
calculating, using the electric signals, information indicating the internal state of the battery on the basis of neural network calculation, the information reflecting a reduction in an effect of polarization of the secondary battery.

16. The apparatus according to claim 15, wherein the calculating step includes
producing, using the electric signals, an input parameter required for calculating the internal state of the battery, the input parameter including i) a polarization-related quantity relating to a charge and discharge current flowing during a latest predetermined period of time which affecting an amount of polarization of the secondary battery and ii) data indicating a voltage of a the secondary battery and a current from and to the secondary battery; and
estimating an output parameter serving as the information indicating the internal state of the battery by applying the input parameter to the neural network calculation.

17. The apparatus according to claim 15, wherein the calculating step includes
producing, using the electric signals, an input parameter required for calculating the internal state of the battery, the input parameter including a functional value correlating to the internal state of the secondary battery, the functional value reflecting the reduction in an effect of polarization of the secondary battery; and
estimating an output parameter serving as the information indicating the internal state of the battery by applying the input parameter to the neural network calculation.
